(19) United States
(12) Patent Application Publication
(10) Pub. No.: US 2025/0130474 A1
(43) Pub. Date: Apr. 24, 2025

(54) DISPLAY DEVICE AND METHOD OF MANUFACTURING THE SAME

(71) Applicant: Samsung Display Co., LTD., Yongin-si (KR)

(72) Inventors: Rang Kyun MOK, Yongin-si (KR); Saet Byeol SHIN, Yongin-si (KR); Tae Ho LEE, Yongin-si (KR); Young Sang HA, Yongin-si (KR)

(73) Assignee: Samsung Display Co., LTD., Yongin-si (KR)

(21) Appl. No.: 18/782,798

(22) Filed: Jul. 24, 2024

(30) Foreign Application Priority Data
Oct. 23, 2023 (KR) 10-2023-0142300

(51) Int. Cl. G02F 1/167; G02F 1/1676; G02F 1/1681

(52) U.S. Cl. CPC G02F 1/167; G02F 1/1676; G02F 1/1681

(57) ABSTRACT

A display device includes a light emitting element, a first electrode disposed on the light emitting element, an electronic ink layer including partition walls disposed on the first electrode, the partition walls including an internal space having a substantially recessed shape to accommodate an electronic ink between the partition walls, a second electrode disposed on the electronic ink layer, and an adhesive layer disposed between the electronic ink layer and the second electrode and adhered to a surface of the electronic ink layer, and a viewing angle is adjusted by moving a carbon particle included in the electronic ink according to a voltage difference between the first electrode and the second electrode.

### CROSS-REFERENCE TO RELATED APPLICATION(S)

This application claims priority to and benefits of Korean Patent Application No. 10-2023-0142300 under 35 U.S.C. § 119, filed on Oct. 23, 2023, in the Korean Intellectual Property Office, the entire contents of which are incorporated herein by reference.

### BACKGROUND

1. Technical Field

The disclosure relates to a display device and a method of manufacturing the same.

2. Description of the Related Art

The importance of a display device is increasing with the development of multimedia. In response to this, various types of display devices, such as an organic light emitting diode (OLED) display device and a liquid crystal display (LCD), are used.

A display device is a device that displays an image and may include a display panel such as an organic light emitting display panel or a liquid crystal display panel. Among them, the organic light emitting display panel (OLED panel) is attracting attention as a next-generation display device due to its advantages such as low-voltage driving, light weight and thinness, a wide viewing angle, and a fast response speed. For example, research on a vehicle display device using an organic light emitting element is recently being conducted. Such a vehicle display device requires a display device and a method of manufacturing the same capable of adjusting a viewing angle by blocking external light that interferes with a passenger's view in case that driving at night.

It is to be understood that this background of the technology section is, in part, intended to provide useful background for understanding the technology. However, this background of the technology section may also include ideas, concepts, or recognitions that were not part of what was known or appreciated by those skilled in the pertinent art prior to a corresponding effective filing date of the subject matter disclosed herein.

### SUMMARY

Embodiments provide a display device with improved efficiency by adjusting a viewing angle and a method of manufacturing the same.

According to an embodiment of the disclosure, a display device may include a light emitting element; a first electrode disposed on the light emitting element; an electronic ink layer including partition walls disposed on the first electrode, the partition walls including an internal space having a substantially recessed shape to accommodate an electronic ink between the partition walls; a second electrode disposed on the electronic ink layer; and an adhesive layer disposed between the electronic ink layer and the second electrode and adhered to a surface of the electronic ink layer; and a viewing angle is adjusted by moving a carbon particle included in the electronic ink according to a voltage difference between the first electrode and the second electrode.

The adhesive layer may be adhered to an upper surface of the partition walls facing the second electrode after a positive voltage is applied to the first electrode and a negative voltage is applied to the second electrode to move the carbon particle toward the first electrode.

The electronic ink layer may further include a base layer disposed on the first electrode to support the partition walls, and the partition walls may protrude from the base layer in a direction toward the second electrode and are spaced apart from each other on the base layer.

Each of the partition walls may have a first surface facing the base layer, and a second surface opposite the first surface and facing the second electrode, and a width of the first surface may be wider than or equal to a width of the second surface.

The first electrode and the second electrode may include indium tin oxide (ITO).

The partition walls and a solvent included in the electronic ink may have a same refractive index.

The partition walls may include resin.

The display device may operate in one of a viewing angle blocking mode and a wide viewing angle mode, in case that the display device operates in the viewing angle blocking mode, the carbon particle may be dispersed and distributed in the internal space, and in case that the display device operates in the wide viewing angle mode, the carbon particle may be distributed adjacent to the first electrode.

The display device may operate in one of a viewing angle blocking mode and a wide viewing angle mode, and in case that the display device operates in the wide viewing angle mode, a positive voltage may be applied to the first electrode and a negative voltage may be applied to the second electrode.

The display device may operate in one of a viewing angle blocking mode and a wide viewing angle mode, and in case that the display device operates in the viewing angle blocking mode, a voltage pulse may be applied to the first electrode and the second electrode.

In the viewing angle blocking mode, a negative voltage may be applied to the second electrode in case that a positive voltage is applied to the first electrode, and a positive voltage may be applied to the second electrode in case that a negative voltage is applied to the first electrode.

Another aspect of the disclosure relates to a method of manufacturing a display device. The method may include forming a first electrode disposed on a light emitting element; forming an electronic ink layer which may including partition walls, the partition walls including an internal space having a substantially recessed shape to accommodate an electronic ink between the partition walls, on the first electrode; forming a second electrode on the electronic ink layer; and forming an adhesive layer disposed between the electronic ink layer and the second electrode and adhered to a surface of the electronic ink layer.

In the method, the forming of the adhesive layer may include adhering the surface of the electronic ink layer to the second electrode after moving a carbon particle included in the electronic ink toward the first electrode due to a positive voltage applied to the first electrode and a negative voltage applied to the second electrode.

In the method, the forming of the electronic ink layer may include injecting the electronic ink into the internal space of the partition walls using liquid crystal dropping (one drop filling (ODF)).

In the method, the electronic ink layer may further include a base layer disposed on the first electrode to support the partition walls, and the partition walls may protrude from the base layer in a direction toward the second electrode and are spaced apart from each other on the base layer.

In the method, the first electrode and the second electrode may include indium tin oxide (ITO).

In the method, the partition walls and a solvent included in the electronic ink may have a same refractive index.

In the method, the partition walls may include resin.

The internal space of the partition walls may have a narrow lower end and a wide upper end.

The method may further include adjusting a viewing angle by moving the carbon particle included in the electronic ink according to a voltage difference between the first electrode and the second electrode.

### BRIEF DESCRIPTION OF THE DRAWINGS

The above and other features of the disclosure will become more apparent by describing in further detail embodiments thereof with reference to the accompanying drawings, in which:

FIG. 1 is a schematic perspective view schematically illustrating a display device according to an embodiment;

FIG. 2 is a block diagram illustrating an embodiment of the display device of FIG. 1;

FIG. 3 is a schematic cross-sectional view taken along line I-I′ of FIG. 1;

FIG. 4 is a schematic cross-sectional view illustrating an embodiment of an electronic ink layer of FIG. 3;

FIG. 5 is a schematic cross-sectional view illustrating an embodiment of the electronic ink layer of FIG. 3;

FIG. 6 is a schematic cross-sectional view illustrating the display device in a step in which an electronic ink is accommodated in the electronic ink layer of FIG. 4 among manufacturing steps of the display device;

FIG. 7 is a schematic cross-sectional view illustrating the display device at a step in which a second electrode and a window are disposed on the electronic ink layer of FIG. 6 among the manufacturing steps of the display device;

FIG. 8 is a schematic cross-sectional view illustrating an embodiment of the display device of FIG. 1 operating in a wide viewing angle mode;

FIG. 9 is a schematic cross-sectional view illustrating an embodiment of the display device of FIG. 1 operating in a viewing angle blocking mode; and

FIG. 10 is a flowchart illustrating an embodiment of a method of manufacturing the display device.

### DETAILED DESCRIPTION OF THE EMBODIMENTS

Hereinafter, embodiments are described in detail with reference to the accompanying drawings. It should be noted that in the following description, portions for understanding an operation according to the disclosure are described, and descriptions of other portions may be omitted in order not to obscure the subject matter of the disclosure. However, the disclosure may be embodied in other forms without being limited to the embodiments described herein. The embodiments described herein are provided to describe in detail to implement the technical spirit of the disclosure to those skilled in the art to which the disclosure pertains.

In the drawings, sizes, thicknesses, ratios, and dimensions of the elements may be exaggerated for ease of description and for clarity. Like numbers refer to like elements throughout.

As used herein, the singular forms, “a,” “an,” and “the” are intended to include the plural forms as well, unless the context clearly indicates otherwise.

In the specification and the claims, the term “and/or” is intended to include any combination of the terms “and” and “or” for the purpose of its meaning and interpretation. For example, “A and/or B” may be understood to mean “A, B, or A and B.” The terms “and” and “or” may be used in the conjunctive or disjunctive sense and may be understood to be equivalent to “and/or.”

In the specification and the claims, the phrase “at least one of” is intended to include the meaning of “at least one selected from the group of” for the purpose of its meaning and interpretation. For example, “at least one of A and B” may be understood to mean “A, B, or A and B.

It will be understood that, although the terms first, second, etc., may be used herein to describe various elements, these elements should not be limited by these terms. These terms are only used to distinguish one element from another element. For example, a first element may be referred to as a second element, and similarly, a second element may be referred to as a first element without departing from the scope of the disclosure.

The spatially relative terms “below”, “beneath”, “lower”, “above”, “upper”, or the like, may be used herein for ease of description to describe the relations between one element or component and another element or component as illustrated in the drawings. It will be understood that the spatially relative terms are intended to encompass different orientations of the device in use or operation, in addition to the orientation depicted in the drawings. For example, in the case where a device illustrated in the drawing is turned over, the device positioned “below” or “beneath” another device may be placed “above” another device. Accordingly, the illustrative term “below” may include both the lower and upper positions. The device may also be oriented in other directions and thus the spatially relative terms may be interpreted differently depending on the orientations.

The terms “overlap” or “overlapped” mean that a first object may be above or below or to a side of a second object, and vice versa. Additionally, the term “overlap” may include layer, stack, face or facing, extending over, covering, or partly covering or any other suitable term as would be appreciated and understood by those of ordinary skill in the art.

The terms “face” and “facing” mean that a first element may directly or indirectly oppose a second element. In a case in which a third element intervenes between the first and second element, the first and second element may be understood as being indirectly opposed to one another, although still facing each other.

When an element is described as ‘not overlapping’ or ‘to not overlap’ another element, this may include that the elements are spaced apart from each other, offset from each other, or set aside from each other or any other suitable term as would be appreciated and understood by those of ordinary skill in the art.

The terms “comprises,” “comprising,” “includes,” and/or “including,”, “has,” “have,” and/or “having,” and variations thereof when used in this specification, specify the presence of stated features, integers, steps, operations, elements, components, and/or groups thereof, but do not preclude the presence or addition of one or more other features, integers, steps, operations, elements, components, and/or groups thereof.

The phrase “in a plan view” means viewing the object from the top, and the phrase “in a schematic cross-sectional view” means viewing a cross-section of which the object is vertically cut from the side.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Unless otherwise defined or implied herein, all terms (including technical and scientific terms) used herein have the same meaning as commonly understood by one of ordinary skill in the art to which the disclosure pertains. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

It will be understood that when an element (or a region, a layer, a portion, or the like) is referred to as “being on”, “connected to” or “coupled to” another element in the specification, it can be directly disposed on, connected or coupled to another element mentioned above, or intervening elements may be disposed therebetween.

It will be understood that the terms “connected to” or “coupled to” may include a physical or electrical connection or coupling.

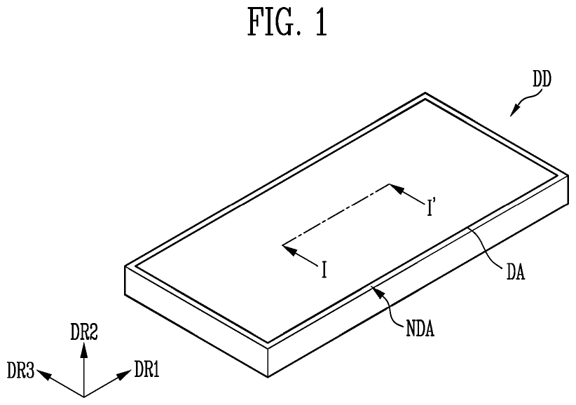

FIG. 1 is a schematic perspective view schematically illustrating a display device according to an embodiment.

Referring to FIG. 1, the display device DD may include a display area DA and a non-display area NDA. The display area DA may be an area that displays an image, and the non-display area NDA may be provided around the display area DA. The non-display area NDA is an area where an image is not displayed. According to an embodiment, a shape of the display area DA and a shape of the non-display area NDA may be variously changed.

In case that the display device DD is an electronic device in which a display surface is applied to one surface or a surface, such as a smartphone, a television, a tablet PC, a mobile phone, a video phone, a car navigation system, an e-book reader, a desktop PC, a laptop PC, a netbook computer, a workstation, a server, a PDA, a portable multimedia player (PMP), an MP3 player, a medical device, a camera, or a wearable, the disclosure may be applied to the display device DD.

The display device DD may be provided in various shapes, and for example, the display device DD may be provided in a rectangular plate shape having two pairs of sides parallel to each other, but the disclosure is not limited thereto. In case that the display device DD is provided in the rectangular plate shape, one pair of sides of the two pairs of sides may be provided longer than the other pair of sides. In the drawing, the display device DD has an angled corner portion formed of a straight line, but the disclosure is not limited thereto. According to an embodiment, the display device DD provided in the rectangular plate shape may have a round shape at a corner portion where one long side or a long side and one short side or a short side contact each other.

In an embodiment of the disclosure, for convenience of description, a case where the display device DD has a rectangular shape having a pair of long sides and a pair of short sides, and an extension direction of the long side may be indicated as a first direction DR1, an extension direction of the short side may be indicated as a third direction DR3, and a direction perpendicular to the extension direction of the long side and the short side may be indicated as a second direction DR2. The first to third directions DR1, DR2, and DR3 may refer to directions indicated by the first to third directions DR1, DR2, and DR3, respectively.

In an embodiment of the disclosure, at least a portion of the display device DD may have flexibility and the portion having the flexibility may be folded.

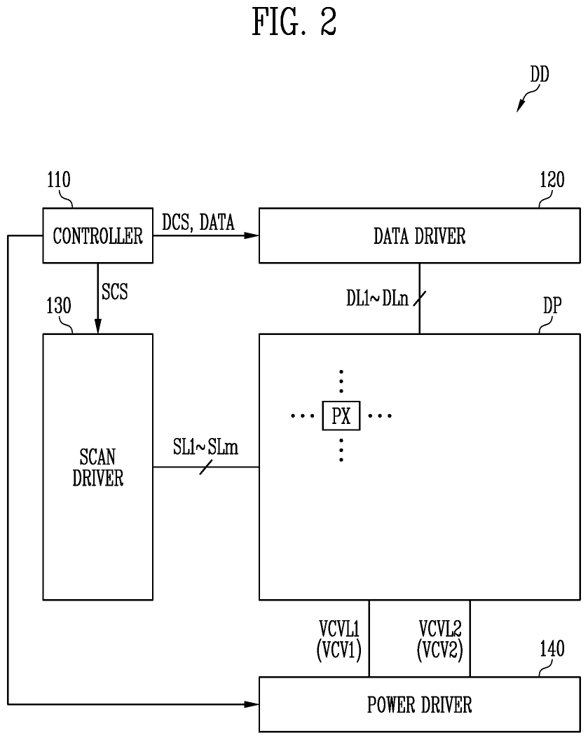

FIG. 2 is a block diagram illustrating an embodiment of the display device of FIG. 1.

Referring to FIG. 2, the display device DD may include a display panel DP, a controller 110, a data driver 120, a scan driver 130, and a power driver 140.

The display panel DP may include pixels PX. The display panel DP may be connected to scan lines SL1 to SLm and data lines DL1 to DLn. The scan lines SL1 to SLm and the data lines DL1 to DLn may be disposed to intersect each other on the display panel DP. The pixels PX may be electrically connected to the scan lines SL1 to SLm and the data lines DL1 to DLn in the display panel DP.

The display panel DP may be of various types of panels, such as an organic light emitting diode (OLED) panel. A type of lines disposed in the display panel DP may vary according to a pixel structure, a panel type, and the like within the spirit and the scope of the disclosure.

The controller 110 may control an operation of the data driver 120, the scan driver 130, and the power driver 140. The controller 110 may provide a first control signal SCS to the scan driver 130 to apply a scan signal to the scan lines SL1 to SLm according to a timing implemented in each frame. The controller 110 may provide an image data signal DATA converted from a data format of an image signal RGB to suit an interface specification of the data driver 120. In case that the scan signal is applied to the scan lines SL1 to SLm, the controller 110 may provide a second control signal DCS to the data driver 120 to apply data voltages to the data lines DL1 to DLn.

The controller 110 may be a timing controller used in display technology, or may be a control device that may perform another control function by including the timing controller.

The data driver 120 may output data signals to the data lines DL1 to DLn. For example, the data driver 120 may receive the second control signal DCS and the image data signal DATA from the controller 110. The data driver 120 may convert the image data signal DATA into the data signals and output the data signals to the data lines DL1 to DLn. Here, the data signals may be analog voltages corresponding to grayscale values of the image data signal DATA. For example, in case that a selectable scan line is selected by the scan driver 130, the data driver 120 may supply analog data voltages to the data lines DL1 to DLn.

The scan driver 130 may receive the first control signal SCS from the controller 110. The scan driver 130 may output a scan signal to the scan lines SL1 to SLm. The scan driver 130 may sequentially supply the scan signals to the scan lines SL1 to SLm according to the first control signal SCS from the controller 110. The pixels PX receiving each scan signal may receive analog voltages of grayscale values corresponding to the image data signal DATA and output light of a luminance corresponding to the analog voltages. Accordingly, an image may be displayed on the display panel DP.

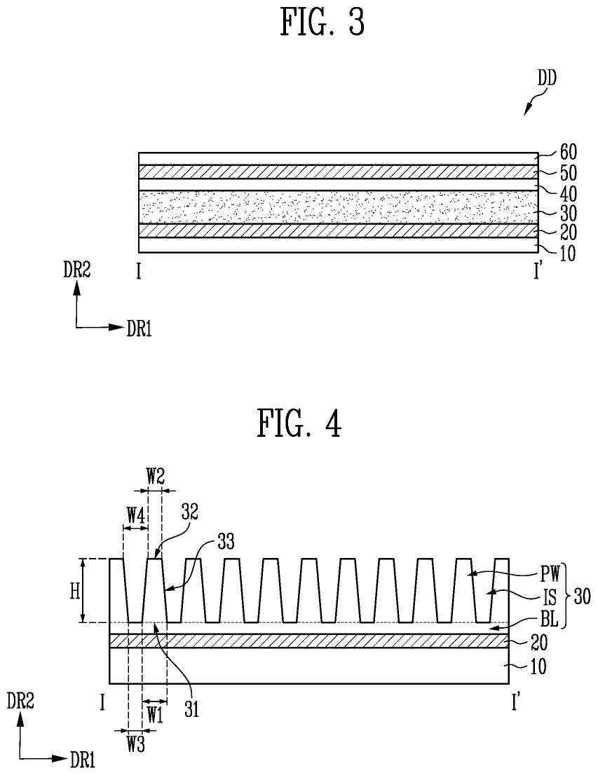

The power driver 140 may generate a first viewing angle control voltage VCV1 and a second viewing angle control voltage VCV2. Although not shown in FIG. 2, the power driver 140 may generate a first power voltage, a second power voltage, an initialization voltage, and the like within the spirit and the scope of the disclosure. The power driver 140 may supply the first viewing angle control voltage VCV1 and the second viewing angle control voltage VCV2 to electrodes of the display panel DP through a first viewing angle control voltage line VCVL1 and a second viewing angle control voltage line VCVL2. The first viewing angle control voltage VCV1 may be a voltage supplied to a first electrode 20 (refer to FIG. 3), and the second viewing angle control voltage VCV2 may be a voltage supplied to a second electrode 50 (refer to FIG. 3). For example, the first viewing angle control voltage VCV1 and the second viewing angle control voltage VCV2 may be determined according to an operation mode of the display device DD. The first viewing angle control voltage VCV1 may be higher than the second viewing angle control voltage VCV2. At this time, the second viewing angle control voltage VCV2 may be a ground voltage or a voltage lower than the ground voltage. The first viewing angle control voltage VCV1 may be lower than the second viewing angle control voltage VCV2. At this time, the first viewing angle control voltage VCV1 may be a ground voltage or a voltage lower than the ground voltage.

At least one of the controller 110, the data driver 120, the scan driver 130, and the power driver 140 may be mounted on the display panel DP in a form of an integrated circuit chip. Another portion of the controller 110, the data driver 120, the scan driver 130, and the power driver 140 may be attached to the display panel DP in a form of a tape carrier package (TCP) or may be mounted on a separate printed circuit board.

FIG. 3 is a schematic cross-sectional view taken along line I-I′ of FIG. 1.

Referring to FIG. 3, the display device DD may include a display module 10, the first electrode 20, an electronic ink layer 30, an adhesive layer 40, the second electrode 50, and a window 60.

The display module 10 may display an image through the display area DA (refer to FIG. 1). The display module 10 may include a display panel capable of self-emission, such as an organic light emitting display panel (OLED panel) that uses organic light emitting diodes as light emitting elements, an ultra small light emitting diode display panel (nano-scale LED display) that uses ultra small light emitting diodes as light emitting elements, and a quantum dot organic light emitting display panel (QD OLED panel) that uses a quantum dot and an organic light emitting diode. The display module 10 may include a non-emissive display panel, such as a liquid crystal display panel (LCD panel), an electro-phoretic display panel (EPD panel), and an electro-wetting display panel (EWD panel). In case that the non-emissive display panel is used, the display device DD may further include a backlight unit that supplies light to the display panel.

The display module 10 may include the pixels PX of FIG. 2. The display module 10 may include a substrate, light emitting elements, and driving circuits for driving the light emitting elements. For example, in case that the light emitting elements are organic light emitting devices, each of the light emitting elements may include a pixel electrode, an organic light emitting layer, and a common electrode. The light emitting element may emit light in case that a hole and an electron injected from the pixel electrode and the common electrode into the organic light emitting layer combine and fall from an excited state to a ground state. The light emitting elements may be connected to the driving circuits, the driving circuits may operate in response to signals and voltages from the data driver 120, the scan driver 130, and the power driver 140 of FIG. 2, and the light emitting elements may emit light according to an operation of the driving circuits.

The first electrode 20 and the second electrode 50 may be disposed on the display module 10. The first electrode 20 and the second electrode 50 may include a transparent conductive material. Even though the first electrode 20 and the second electrode 50 are disposed on the display module 10, the first electrode 20 and the second electrode 50 may transmit light incident from a lower portion. For example, the first electrode 20 and the second electrode 50 may include indium tin oxide (ITO). The first electrode 20 and the second electrode 50 may include indium zinc oxide (IZO), indium tin zinc oxide (ITZO), or aluminum zinc oxide (AZO). However, the disclosure is not limited thereto.

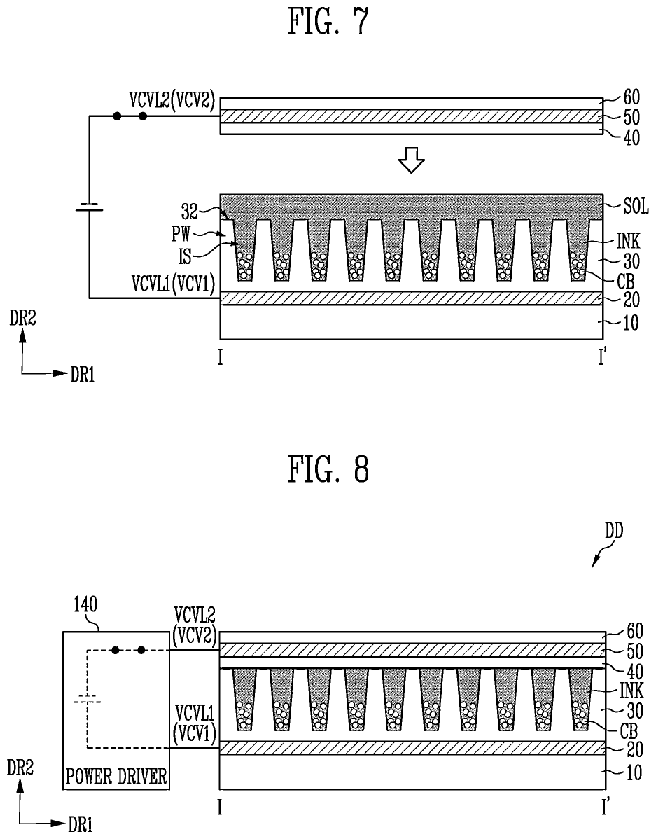

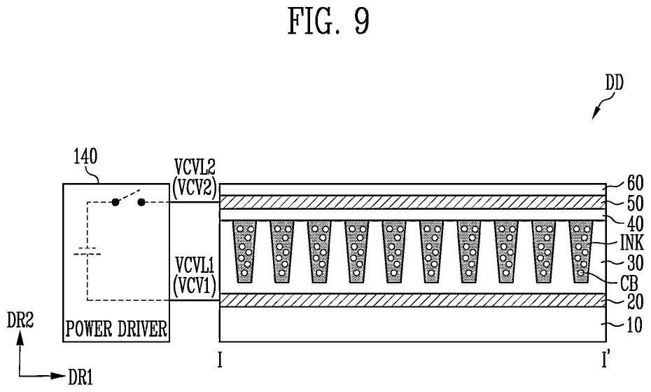

The electronic ink layer 30 may be disposed between the first electrode 20 and the second electrode 50. The electronic ink layer 30 may include an electronic ink. Here, the electronic ink may include a solvent and carbon particles dispersed in the solvent. Accordingly, a light transmittance of the electronic ink layer 30 may be controlled according to a voltage difference between the first electrode 20 and the second electrode 50. In other words, the light transmittance of the electronic ink layer 30 may be controlled according to the first viewing angle control voltage VCV1 (refer to FIG. 2) applied to the first electrode 20 and the second viewing angle control voltage VCV2 (refer to FIG. 2) applied to the second electrode 50, and thus the display device DD may operate in a viewing angle blocking mode and a wide viewing angle mode. A detailed description of the electronic ink layer 30 according to the operation mode of the display device DD is described later with reference to FIGS. 8 and 9.

The adhesive layer 40 may be disposed between the electronic ink layer 30 and the second electrode 50 and may be adhered to one surface or a surface of the electronic ink layer 30 and one surface or a surface of the second electrode 50. The adhesive layer 40 may include a material with high light transmittance, such as an adhesive film or resin. The adhesive layer 40 may include at least one of optical clear resin (OCR), optical clear adhesive (OCA), and pressure sensitive adhesive (PSA).

The window 60 may protect the display panel from external impact and provide an input surface and/or a display surface to a user. For example, the window 60 may have multiple layer structure selected from a glass substrate, a plastic film, and a plastic substrate. The multiple layer structure may be formed through a continuous process or an adhesion process using an adhesive layer. A portion of the window 60 or the entire window 60 may have flexibility.

FIG. 4 is a schematic cross-sectional view illustrating an embodiment of the electronic ink layer of FIG. 3.

Referring to FIG. 4, the electronic ink layer 30 may include partition walls PW. The electronic ink layer 30 may define internal spaces IS that may accommodate the electronic ink between the partition walls PW. The electronic ink layer 30 may further include a base layer BL disposed on the first electrode 20 to support the partition walls PW.

The partition walls PW may protrude from a base layer BL in the second direction DR2. For example, the second direction DR2 may be a thickness direction of the electronic ink layer 30. The partition walls PW may be disposed spaced apart from each other in a direction perpendicular to the second direction DR2 on the base layer BL. For example, each of the partition walls PW may have a first surface 31 facing the base layer BL and a second surface 32 facing the second electrode 50. The first surface 31 and the second surface 32 may be opposite surfaces. A width W1 of the first surface 31 may be wider than or equal to a width W2 of the second surface 32. Each of the partition walls PW may have a side surface 33 connecting the first surface 31 and the second surface 32. The side surface 33 of the partition walls PW may have a taper shape. Accordingly, a cross-section of each of the partition walls PW may have a trapezoidal shape.

The partition walls PW may include a transparent polymer insulating material. The partition walls PW may be a single layer or multiple layers. However, a configuration material and/or a stack structure of the partition walls PW are/is not limited thereto.

Since the side surface 33 of each of the partition walls PW has the taper shape, the internal spaces IS positioned between the partition walls PW may have a shape complementary to the taper shape, for example, an inverted trapezoid shape. It may be understood that the internal spaces IS have the same depth as a height H at which the partition walls PW protrude from the base layer BL. For example, the internal spaces IS may have a depth corresponding to the height H between the first surface 31 and the second surface 32 of the partition walls PW. The internal spaces IS may have a third width W3 at a height of the first surface 31 of the partition walls PW. The internal spaces IS may have a fourth width W4 at a height of the second surface 32 of the partition walls PW. At this time, the third width W3 may be equal to or narrower than the fourth width W4. By way of example, the third width W3 of the internal spaces IS may be about 10 μm, and the fourth width W4 of the internal spaces IS may be about 20 μm. The depth of the internal spaces IS may be in a range of about 50 to about 100 μm. A distance between the internal spaces IS may be about 45 μm, which may be the width W1 of the first surface 31 of the partition walls PW. However, this is an example and is not limited thereto.

Each of the internal spaces IS may have a substantially recessed shape between the partition walls PW. The substantially recessed shape of each of the internal spaces IS may be formed by a physical processing method such as a master mold process, an imprinting process, or a photolithography process. Accordingly, the internal spaces IS may have a shape in which the first surface 31 which is a lower end is narrow and the second surface 32 which is an upper end is wide. The internal spaces IS may be formed to be spaced apart from the first electrode 20 by the base layer BL. In this case, productivity reduction and a defect due to leakage of the electronic ink accommodated in the internal spaces IS may be prevented.

Each of the internal spaces IS may have a closed planar shape when viewed in the direction opposite to the second direction DR2. A planar shape of each of the internal spaces IS may be a quadrangular shape, a circular shape, or a shape in which a curve and a straight line are combined. However, the disclosure is not limited thereto as long as the electronic ink may be accommodated.

FIG. 5 is a schematic cross-sectional view illustrating an embodiment of the electronic ink layer of FIG. 3.

Referring to FIG. 5, the electronic ink layer 30 may include partition walls PW′, each of which has a rectangular shape.

The partition walls PW′ may protrude from the first electrode 20 in the second direction DR2. The partition walls PW′ may be disposed spaced apart from each other in a direction perpendicular to the second direction DR2 on the first electrode 20. For example, each of the partition walls PW′ may have a first surface 34 facing the first electrode 20 and a second surface 35 facing the second electrode 50. The first surface 34 and the second surface 35 may be surfaces facing each other.

A cross-section of each of the partition walls PW′ may have a short side in the first direction DR1 and a long side in the second direction DR2. Each of the partition walls PW′ may have the same width W5 from the first surface 34 to the second surface 35. Accordingly, the cross-section of each of the partition walls PW′ may have a rectangular shape.

As a side surface 36 of the partition walls PW′ extend perpendicularly to the first electrode 20, each of internal spaces IS′ positioned between the partition walls PW′ may also have a rectangular shape. For example, each of the internal spaces IS′ may have the same width W6 between the first surface 34 and the second surface 35. The internal spaces IS may have a depth equal to a height H′ of the partition walls PW.

As described above, the partition walls PW′ may have various shapes, but are not limited thereto.

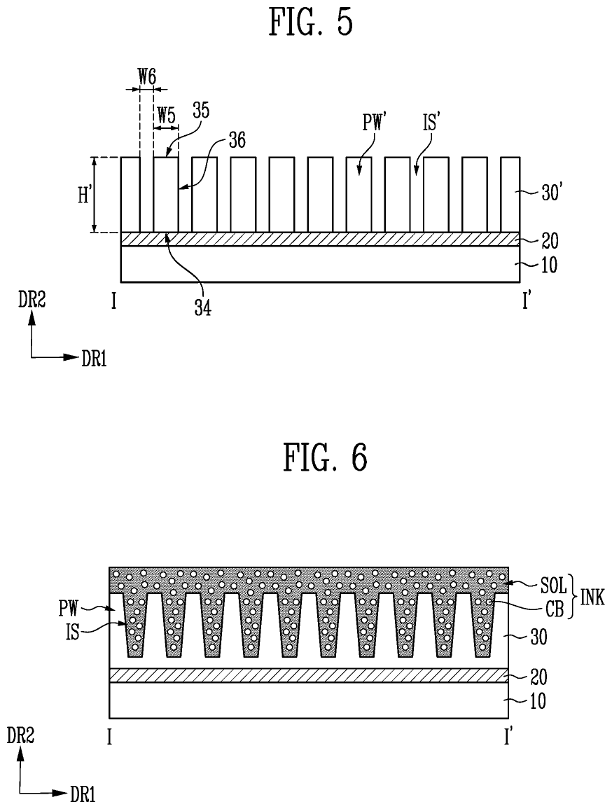

FIG. 6 is a schematic cross-sectional view illustrating the display device in a step in which the electronic ink is accommodated in the electronic ink layer of FIG. 4 among manufacturing steps of the display device.

Referring to FIG. 6, the electronic ink layer 30 may accommodate the electronic ink INK capable of absorbing light in the internal spaces IS.

The electronic ink INK may be injected into the internal spaces IS using liquid crystal dropping (one drop filling (ODF)) to cover the electronic ink layer 30. The electronic ink INK may be injected into the internal spaces IS using an inkjet, liquid dispensing, or the like, and is not limited thereto. However, as the electronic ink INK is applied to an open surface of the electronic ink layer 30, the electronic ink INK may remain not only in the internal spaces IS but also on the second surface 32 (refer to FIG. 5) of the partition walls PW. The electronic ink INK remaining on the second surface 32 of the partition walls PW may form a residual film layer. For example, carbon particles CB included in the electronic ink INK may remain in the residual film layer formed on the second surface 32 of the partition walls PW.

The electronic ink INK may include a solvent SOL and the carbon particles CB dispersed in the solvent SOL. For example, the carbon particles CB may be colored carbon nanotube particles and may be carbon black, manganese ferrite black spinel, copper chromite black spinel, or the like within the spirit and the scope of the disclosure. The solvent SOL may be a transparent, may be a low-viscosity insulating solvent, and may be a fluid or oil.

The solvent SOL may have the same refractive index as the partition walls PW. For example, in case that the partition walls PW include transparent resin with a refractive index of 1.41, the solvent SOL may be oil with a refractive index of 1.41. For example, the solvent SOL has the same refractive index as the partition walls PW, thereby minimizing total reflection and ensuring a constant transmittance.

The carbon particles CB may absorb light incident from the outside in the electronic ink INK. The solvent SOL may uniformly disperse the carbon particles CB in the internal spaces IS and prevent the carbon particles CB from settling due to gravity.

The carbon particles CB may be black colored particles and may be particles charged with a negative charge (or a positive charge). In case that an electric field is formed, the carbon particles CB may be moved by electric force. For example, in case that electric force does not act on the carbon particles CB, the carbon particles CB may be uniformly dispersed and distributed in the solvent SOL. On the other hand, in case that the electric force acts on the carbon particles CB, the carbon particles CB may be distributed adjacent to a given position in the solvent SOL.

FIG. 7 is a schematic cross-sectional view illustrating the display device in a step in which the second electrode 50 and the window 60 are disposed on the electronic ink layer of FIG. 6 among manufacturing steps of the display device.

Referring to FIGS. 6 and 7, the second electrode 50 and the window 60 are disposed on the electronic ink layer 30 in which the electronic ink INK is accommodated. The adhesive layer 40 may be formed on a lower surface of the second electrode 50 and may be disposed between the second electrode 50 and the electronic ink layer 30.

In case that the adhesive layer 40 is adhered to the electronic ink layer 30 in a state in which the electronic ink INK remains on the second surface 32 of the partition walls PW, transmittance may be reduced due to the carbon particles CB included in the electronic ink INK. On the other hand, according to an embodiment, the carbon particles CB included in the electronic ink INK may be moved to the internal spaces IS, and the adhesive layer 40 may be adhered to the electronic ink layer 30.

First, a voltage for forming an electric field may be applied to the first electrode 20 and the second electrode 50 with the electronic ink layer 30 disposed between the first electrode 20 and the second electrode 50. For example, the first viewing angle control voltage VCV1 may be applied to the first electrode 20 through the first viewing angle control voltage line VCVL1. The second viewing angle control voltage VCV2 may be applied to the second electrode 50 through the second viewing angle control voltage line VCVL2. In this case, an electric field may be formed in the electronic ink layer 30. At this time, the first viewing angle control voltage VCV1 may be a positive voltage, and the second viewing angle control voltage VCV2 may be a ground voltage or a negative voltage. As a voltage difference between the first electrode 20 and the second electrode 50 increases, an intensity of the electric field formed in the electronic ink layer 30 may increase. By way of example, the first viewing angle control voltage VCV1 may be a voltage of about 100V or more, and the second viewing angle control voltage VCV2 may be a voltage of about 0V or less. However, the disclosure is not limited thereto.

The carbon particles CB charged with a negative charge by the formed electric field may receive electrical attraction. The carbon particles CB receiving the electrical attraction may move to an area adjacent to the first electrode 20 to which a positive voltage is applied in the internal spaces IS. For example, the carbon particles CB included in the electronic ink INK may be distributed adjacent to the first electrode 20 in the internal spaces IS. On the other hand, only the solvent SOL excluding the carbon particles CB may remain in the residual film layer formed on the second surface 32 of the partition walls PW. In this state, the adhesive layer 40 may be adhered to the second surface 32 of the partition walls PW to bond the electronic ink layer 30 between the first electrode 20 and the second electrode 50.

According to an example, a voltage applied in case that adhering the electronic ink layer 30 and the adhesive layer 40 may be a high voltage so that the carbon particles CB do not remain between the bonded electronic ink layer 30 and adhesive layer 40. The voltage applied in case that adhering the electronic ink layer 30 and the adhesive layer 40 may be higher than the voltage applied to the first electrode 20 according to the operation mode of the display device after the display device is manufactured.

As described above, in a state in which the voltage is applied to the first electrode 20 and the second electrode 50, the second electrode 50 may be adhered to the electronic ink layer 30 through the adhesive layer 40. In this case, only the solvent SOL excluding the carbon particles CB may remain between the electronic ink layer 30 and the adhesive layer 40. Therefore, a problem that transmittance of an upper surface of the electronic ink layer 30 is reduced due to the carbon particles CB included in the electronic ink INK may be improved.

FIG. 8 is a schematic cross-sectional view illustrating an embodiment of the display device of FIG. 1 operating in the wide viewing angle mode.

Referring to FIG. 8, in case that the electric field is formed between the first electrode 20 and the second electrode 50, the display device DD may operate in the wide viewing angle mode. According to an example, in case that the electric field is formed between the first electrode 20 and the second electrode 50, the carbon particles CB may not be uniformly dispersed in the solvent SOL. The carbon particles CB may be distributed adjacent to the first electrode 20 in the internal spaces IS. In an area which is not adjacent to the first electrode 20 among the internal spaces IS, only the solvent SOL may remain without the carbon particles CB. The solvent SOL disposed in the area which is not adjacent to the first electrode 20 among the internal spaces IS may transmit incident light with the same transmittance as the partition walls PW. In this case, in the electronic ink layer 30, optical openings that allow light emitted from the display module 10 to pass may be expanded. Accordingly, the display device DD may operate in the wide viewing angle mode in which external light may transmit through the display device DD. In the wide viewing angle mode, the display device DD may function as a transparent display device.

In order to form the electric field between the first electrode 20 and the second electrode 50, voltages may be applied to the first electrode 20 and the second electrode 50, respectively. A positive voltage may be applied to the first electrode 20 during a preset time, and a ground voltage or a negative voltage may be applied to the second electrode 50 during a preset time. Here, a time in case that the voltages are applied to the first electrode 20 and the second electrode 50 may be set to a range of about 1 s to about 2 s. By way of example, in case that the first viewing angle control voltage VCV1 of about 10V or more and about 50V or less is applied to the first electrode 20, the second viewing angle control voltage VCV2 of about 0V or less may be applied to the second electrode 50. However, this is an example and is not limited thereto.

As described above, as the carbon particles CB that block light are distributed adjacent to the first electrode 20, optical openings may be expanded in an upper portion of the internal spaces IS. Accordingly, the display device DD may operate in the wide viewing angle mode that transmits light. Therefore, the display device DD may prevent a decrease in luminance by moving the carbon particles CB to open a light emission path.

FIG. 9 is a schematic cross-sectional view illustrating an embodiment of the display device of FIG. 1 operating in the viewing angle blocking mode.

Referring to FIG. 9, in case that the electric field is not formed between the first electrode 20 and the second electrode 50, the display device DD may operate in the viewing angle blocking mode. According to an example, in case that a voltage is not applied to the first electrode 20 and the second electrode 50, an electric field may not be formed between the first electrode 20 and the second electrode 50. In this case, electric force may not act on the carbon particles CB included in the electronic ink INK. Accordingly, the carbon particles CB may be uniformly dispersed in the solvent SOL and dispersed and distributed in the internal spaces IS. As the carbon particles CB are dispersed and distributed in the internal spaces IS, the dispersed carbon particles CB may absorb incident light. For example, in case that an electric field is not formed between the first electrode 20 and the second electrode 50, light incident at a viewing angle of a certain angle or more may be blocked by the carbon particles CB dispersed in the internal spaces IS. Accordingly, the display device DD may operate in the viewing angle blocking mode that does not transmit external light. Therefore, the display device DD may improve visibility of an image displayed on the display panel by blocking external light.

As another example, in order to relatively quickly switch from the wide viewing angle mode to the viewing angle blocking mode, the electric field formed between the first electrode 20 and the second electrode 50 is required to be removed relatively quickly. In this case, a voltage pulse may be applied to each of the first electrode 20 and the second electrode 50. A positive voltage and a negative voltage may be alternately applied to each of the first electrode 20 and the second electrode 50 during a preset time. Here, a time in case that the voltage is applied to the first electrode 20 and the second electrode 50 may be set to three or more times of about 100 ms to about 200 ms. However, this is an example and is not limited thereto. For example, in case that a positive voltage is applied to the first electrode 20, a negative voltage may be applied to the second electrode 50. In case that a negative voltage is applied to the first electrode 20, a positive voltage may be applied to the second electrode 50. By way of example, in case that the first viewing angle control voltage VCV1 of about 10V or more and about 50V or less is applied to the first electrode 20, the second viewing angle control voltage VCV2 of about 0V or less may be applied to the second electrode 50. In case that the first viewing angle control voltage VCV1 of about 0V or less is applied to the first electrode 20, the second viewing angle control voltage VCV2 of about 10V or more and about 50V or less may be applied to the second electrode 50. For example, the display device DD may relatively quickly switch from the wide viewing angle mode to the viewing angle blocking mode by applying the voltage pulse to each of the first electrode 20 and the second electrode 50. Therefore, the display device DD may quickly perform mode switching according to a user's need.

Hereinafter, a method of manufacturing the display device described with reference to FIGS. 1 to 9 is described.

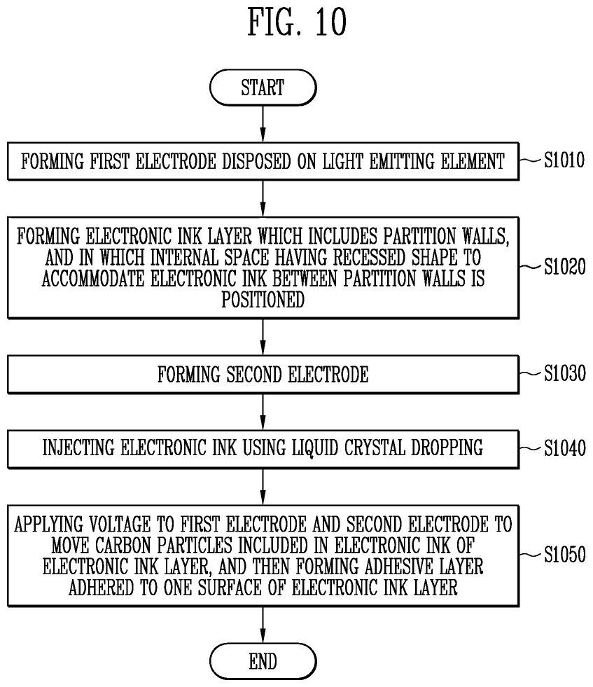

FIG. 10 is a flowchart illustrating an embodiment of a method of manufacturing the display device. An overlapping content described with reference to FIGS. 1 to 9 may be omitted.

Referring to FIGS. 3 and 10, in S1010, the first electrode 20 may be formed on the display module 10.

Referring to FIGS. 4 and 10, in S1020, the electronic ink layer 30 which may include the partition walls PW, and in which the internal spaces IS having the substantially recessed shape to accommodate the electronic ink INK between the partition walls PW is positioned may be formed.

According to an embodiment, the electronic ink layer 30 may include partition walls PW protruding from the base layer BL in the second direction DR2. The partition walls PW may be disposed spaced apart from each other in the direction perpendicular to the second direction DR2 on the base layer BL. For example, each of the partition walls PW may have the first surface 31 facing the base layer BL and the second surface 32 facing the second electrode 50. The first surface 31 and the second surface 32 may be surfaces facing each other. The width W1 of the first surface 31 may be wider than or equal to the width W2 of the second surface 32. Each of the partition walls PW may have the side surface 33 connecting the first surface 31 and the second surface 32. The side surface 33 of each of the partition walls PW may have a taper shape. A cross-section of each of the partition walls PW may have a trapezoidal shape.

The partition walls PW may include a transparent polymer insulating material. For example, the adhesive layer 40 may include a material with high light transmittance, such as an adhesive film or resin.

The electronic ink layer 30 may define the internal spaces IS having the substantially recessed shape between the partition walls PW. The substantially recessed shape of the internal spaces IS may be formed by a physical processing method such as a master mold process, an imprinting process, or a photolithography process.

Since the side surfaces 33 of the partition walls PW have the taper shape, each of the internal spaces IS positioned between the partition walls PW may have a shape complementary to the taper shape, for example, an inverted trapezoid shape. Each of the internal spaces IS may have a depth equal to the height H at which the partition walls PW protrude from the base layer BL.

Referring to FIGS. 7 and 10, in S1030, the second electrode 50 may be formed.

Referring to FIGS. 6 and 10, in S1040, the electronic ink INK may be injected into the internal spaces IS of the electronic ink layer 30 using liquid crystal dropping (ODF).

According to an embodiment, the electronic ink INK may be injected into the internal spaces IS using liquid crystal dropping (one drop filling (ODF)) to cover the electronic ink layer 30. The electronic ink INK may be injected into the internal spaces IS using an inkjet, liquid dispensing, or the like, and is not limited thereto. However, as the electronic ink INK is applied to an open surface of the electronic ink layer 30, the electronic ink INK may remain not only in the internal spaces IS but also on the second surface 32 of the partition walls PW. The electronic ink INK remaining on the second surface 32 of the partition walls PW may form a residual film layer. For example, the carbon particles CB included in the electronic ink INK may remain in the residual film layer formed on the second surface 32 of the partition walls PW.

The electronic ink INK may include the solvent SOL and the carbon particles CB dispersed in the solvent SOL. For example, the carbon particles CB may be colored carbon nanotube particles and may be carbon black, manganese ferrite black spinel, copper chromite black spinel, or the like within the spirit and the scope of the disclosure. The solvent SOL may be a transparent, may be a low-viscosity insulating solvent, and may be a fluid or oil.

The carbon particles CB may function of absorbing light substantially incident from the outside in the electronic ink INK. The carbon particles CB may be black colored particles and may be particles charged with a negative charge (or a positive charge). In case that an electric field is formed, the carbon particles CB may be moved by electric force. For example, in case that electric force does not act on the carbon particles CB, the carbon particles CB may be uniformly dispersed and distributed in the solvent SOL. On the other hand, in case that the electric force acts on the carbon particles CB, the carbon particles CB may be distributed adjacent to a given position in the solvent SOL.

Referring to FIGS. 7 and 10, in S1050, a voltage may be applied to the first electrode 20 and the second electrode 50 to move the carbon particles CB included in the electronic ink INK of the electronic ink layer 30, and the adhesive layer 40 adhered to one surface or a surface of the electronic ink layer 30 may be formed.

In case that the adhesive layer 40 is adhered to the electronic ink layer 30 in a state in which the electronic ink INK remains on the second surface 32 of the partition walls PW, transmittance may be reduced due to the carbon particles CB included in the electronic ink INK. On the other hand, according to an embodiment, the carbon particles CB included in the electronic ink INK may be moved to the internal spaces IS on the second surface 32 of the partition walls PW, and the adhesive layer 40 may be adhered to the electronic ink layer 30.

First, the voltage for forming the electric field may be applied to the first electrode 20 and the second electrode 50 with the electronic ink layer 30 disposed between the first electrode 20 and the second electrode 50. For example, the first viewing angle control voltage VCV1 may be applied to the first electrode 20 through the first viewing angle control voltage line VCVL1. The second viewing angle control voltage VCV2 may be applied to the second electrode 50 through the second viewing angle control voltage line VCVL2. In this case, the electric field may be formed in the electronic ink layer 30. At this time, the first viewing angle control voltage VCV1 may be a positive voltage, and the second viewing angle control voltage VCV2 may be a ground voltage or a negative voltage. As a voltage difference between the first electrode 20 and the second electrode 50 increases, an intensity of the electric field formed in the electronic ink layer 30 may increase. By way of example, the first viewing angle control voltage VCV1 may be a voltage of about 100V or more, and the second viewing angle control voltage VCV2 may be a voltage of about 0V or less. However, the disclosure is not limited thereto.

The carbon particles CB charged with a negative charge by the formed electric field may receive electrical attraction. The carbon particles CB receiving the electrical attraction may move to an area adjacent to the first electrode 20 to which a positive voltage is applied in the internal spaces IS. For example, the carbon particles CB included in the electronic ink INK may be distributed adjacent to the first electrode 20 in the internal spaces IS. On the other hand, only the solvent SOL excluding the carbon particles CB may remain in the residual film layer formed on the second surface 32 of the partition walls PW. In this state, the adhesive layer 40 may be adhered to the second surface 32 of the partition walls PW to bond the electronic ink layer 30 between the first electrode 20 and the second electrode 50.

According to an example, a voltage applied in case that adhering the electronic ink layer 30 and the adhesive layer 40 may be a high voltage so that the carbon particles CB do not remain between the bonded electronic ink layer 30 and adhesive layer 40. The voltage applied in case that adhering the electronic ink layer 30 and the adhesive layer 40 may be higher than the voltage applied to the first electrode 20 according to the operation mode of the display device after the display device is manufactured.

As described above, in a state in which the voltage is applied to the first electrode 20 and the second electrode 50, the second electrode 50 may be adhered to the electronic ink layer 30 through the adhesive layer 40. In this case, only the solvent SOL excluding the carbon particles CB may remain between the electronic ink layer 30 and the adhesive layer 40. Therefore, a problem that transmittance of an upper surface of the electronic ink layer 30 is reduced due to the carbon particles CB included in the electronic ink INK may be improved.

According to embodiments, a display device with improved efficiency by adjusting a viewing angle and a method of manufacturing the same are provided.

An effect according to embodiments is not limited to the content described above, and further various effects are included in the specification.

Although embodiments and application examples are described herein, other embodiments and modifications may be derived from the above description. Therefore, the spirit of the disclosure is not limited to these embodiments, and extends to the scope of the claims set forth below, various modifications, and equivalents.

What is claimed is:

1. A display device comprising:
a light emitting element;
a first electrode disposed on the light emitting element;
an electronic ink layer including partition walls disposed on the first electrode, the partition walls include an internal space having a substantially recessed shape to accommodate an electronic ink between the partition walls;
a second electrode disposed on the electronic ink layer; and
an adhesive layer disposed between the electronic ink layer and the second electrode and adhered to a surface of the electronic ink layer,
wherein a viewing angle is adjusted by moving a carbon particle included in the electronic ink according to a voltage difference between the first electrode and the second electrode.

2. The display device according to claim 1, wherein the adhesive layer is adhered to an upper surface of the partition walls facing the second electrode after a positive voltage is applied to the first electrode and a negative voltage is applied to the second electrode to move the carbon particle toward the first electrode.

3. The display device according to claim 1, wherein
the electronic ink layer further includes a base layer disposed on the first electrode to support the partition walls, and
the partition walls protrude from the base layer in a direction toward the second electrode and are spaced apart from each other on the base layer.

4. The display device according to claim 3, wherein
each of the partition walls has a first surface facing the base layer, and a second surface opposite the first surface and facing the second electrode, and
a width of the first surface is wider than or equal to a width of the second surface.

5. The display device according to claim 1, wherein the first electrode and the second electrode include indium tin oxide (ITO).

6. The display device according to claim 1, wherein the partition walls and a solvent included in the electronic ink have a same refractive index.

7. The display device according to claim 1, wherein the partition walls include resin.

8. The display device according to claim 1, wherein
the display device operates in one of a viewing angle blocking mode and a wide viewing angle mode,
in case that the display device operates in the viewing angle blocking mode, the carbon particle is dispersed and distributed in the internal space of the partition walls, and
in case that the display device operates in the wide viewing angle mode, the carbon particle is distributed adjacent to the first electrode.

9. The display device according to claim 1, wherein
the display device operates in one of a viewing angle blocking mode and a wide viewing angle mode, and
in case that the display device operates in the wide viewing angle mode, a positive voltage is applied to the first electrode and a negative voltage is applied to the second electrode.

10. The display device according to claim 1, wherein
the display device operates in one of a viewing angle blocking mode and a wide viewing angle mode, and
in case that the display device operates in the viewing angle blocking mode, a voltage pulse is applied to the first electrode and the second electrode.

11. The display device according to claim 10, wherein in the viewing angle blocking mode, a negative voltage is applied to the second electrode in case that a positive voltage is applied to the first electrode, and a positive voltage is applied to the second electrode in case that a negative voltage is applied to the first electrode.

12. A method of manufacturing a display device, the method comprising:
forming a first electrode disposed on a light emitting element;
forming an electronic ink layer including partition walls, the partition walls including an internal space having a substantially recessed shape to accommodate an electronic ink between the partition walls on the first electrode;
forming a second electrode on the electronic ink layer; and
forming an adhesive layer disposed between the electronic ink layer and the second electrode and adhered to a surface of the electronic ink layer.

13. The method according to claim 12, wherein the forming of the adhesive layer comprises adhering the surface of the electronic ink layer to the second electrode after moving a carbon particle included in the electronic ink toward the first electrode due to a positive voltage applied to the first electrode and a negative voltage applied to the second electrode.

14. The method according to claim 12, wherein the forming of the electronic ink layer comprises injecting the electronic ink into the internal space of the partition walls using liquid crystal dropping (one drop filling (ODF)).

15. The method according to claim 12, wherein
the electronic ink layer further includes a base layer disposed on the first electrode that supports the partition walls, and
the partition walls protrude from the base layer in a direction toward the second electrode and are spaced apart from each other on the base layer.

16. The method according to claim 12, wherein the first electrode and the second electrode include indium tin oxide (ITO).

17. The method according to claim 12, wherein the partition walls and a solvent included in the electronic ink have a same refractive index.

18. The method according to claim 12, wherein the partition walls include resin.

19. The display device according to claim 1, wherein the internal space of the partition walls has a narrow lower end and a wide upper end.

20. The method according to claim 12, further comprising:
adjusting a viewing angle by moving the carbon particle included in the electronic ink according to a voltage difference between the first electrode and the second electrode.
